(19) United States
(12) Patent Application Publication
(10) Pub. No.: US 2024/0321645 A1
(43) Pub. Date: Sep. 26, 2024

(54) CONTACT CUT AND WRAP AROUND CONTACT

(71) Applicant: INTERNATIONAL BUSINESS MACHINES CORPORATION, Armonk, NY (US)

(72) Inventors: Juntao Li, Cohoes, NY (US); Julien Frougier, Albany, NY (US); Nicolas Jean Loubet, Guilderland, NY (US); Chanro Park, Clifton Park, NY (US); Min Gyu Sung, Latham, NY (US); Ruilong Xie, Niskayuna, NY (US)

(21) Appl. No.: 18/188,496

(22) Filed: Mar. 23, 2023

(51) Int. Cl. H01L 21/8234; H01L 27/088

(52) U.S. Cl. CPC H01L 21/823475; H01L 21/823418; H01L 21/823481; H01L 27/088

(57) ABSTRACT

A microelectronic device including a first nanosheet transistor includes a first source/drain and a second nanosheet transistor includes a second source/drain. The first source/drain and the second source/drain are adjacent to each other. Each of the first source/drain and the second source/drain have an asymmetrical profile when cut through the first and second source/drain.

### BACKGROUND

The present invention generally relates to the field of microelectronics, and more particularly to formation of gouges in the source/drain for the formation of contacts.

Nanosheet is the lead device architecture in continuing CMOS scaling. However, nanosheet technology has shown issues when scaling down such that as the devices become smaller and closer together, they are interfering with each other. With the number of devices being fit in a smaller area it is causing components to be located closer together which can cause shorts between the components.

### BRIEF SUMMARY

Additional aspects and/or advantages will be set forth in part in the description which follows and, in part, will be apparent from the description, or may be learned by practice of the invention.

A microelectronic device including a first nanosheet transistor includes a first source/drain and a second nanosheet transistor includes a second source/drain. The first source/drain and the second source/drain are adjacent to each other. Each of the first source/drain and the second source/drain have an asymmetrical profile when cut through the first and second source/drain.

A microelectronic device including a first nanosheet transistor includes a first source/drain and a second nanosheet transistor includes a second source/drain. A first source/drain contact and a second source/drain contact. The first source/drain and the second source/drain are adjacent to each other. Each of the first source/drain and the second source/drain have an asymmetrical profile when cut through the first and second source/drain. The combined first source/drain and the second source/drain have a substantially symmetrical proofed when cut through the first and second source/drain.

A method including the steps of forming a first nanosheet transistor includes a first source/drain and forming a second nanosheet transistor includes a second source/drain. Forming a first semiconductor alloy liner on top of the first source/drain and the second source/drain. Forming a shared source/drain contact, where the shared source/drain contact extends over both the first source/drain and the second source/drain. Forming a first trench, where the first trench divides the shared source/drain contact in to a first source/drain contact and a second source/drain contact. The first trench exposes the first source/drain and the second source/drain. Laterally etching the first source/drain and the second source/drain. The laterally etching extends outwards from the first trench. After the etching process each of the first source/drain and the second source/drain have an asymmetrical profile when cut through the first and second source/drain.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of multiple nano devices or transistors, in accordance with the embodiment of the present invention.

FIG. 2 illustrates a cross section Y of the source/drain region after the formation of the source/drains, in accordance with the embodiment of the present invention.

FIG. 3 illustrates a cross section Y of the source/drain region after the formation of a first semiconductor alloy liner and a shared contact, in accordance with the embodiment of the present invention.

FIG. 4 illustrates a cross section Y of the source/drain region after the formation of a hardmask and a shared contact cut, in accordance with the embodiment of the present invention.

FIG. 5 illustrates a cross section Y of the source/drain region after a selective lateral etch of the source/drains, in accordance with the embodiment of the present invention.

FIG. 6 illustrates a cross section Y of the source/drain region after the formation of a second semiconductor alloy liner and formation of metal plugs, in accordance with the embodiment of the present invention.

FIG. 7 illustrates a cross section Y of the source/drain region after the removal of excess materials and formation of cut trench, in accordance with the embodiment of the present invention.

FIG. 8 illustrates a cross section Y of the source/drain region after the formation of a dielectric pillar, in accordance with the embodiment of the present invention.

FIG. 9 illustrates a cross section Y of the source/drain region after the formation of additional interlayer dielectric material, contact vias, and a plurality of metal lines, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards creating/forming an asymmetrical source/drain to increase the spacing/distance between adjacent source/drains. By increasing the spacing/distance the chance of the adjacent source/drains from shorting each other is reduced. The increase of the spacing/distance is achieved by laterally etching the source/drains from the area where the adjacent source/drains are closest to each other.

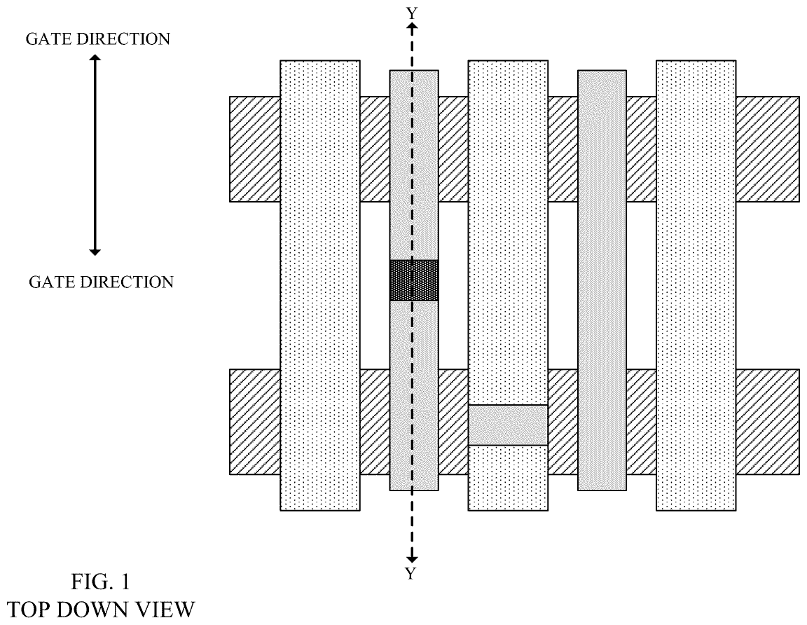

FIG. 1 illustrates a top-down view of multiple devices, in accordance with the embodiment of the present invention. Cross-section Y is a cross section through a source/drain region that illustrates adjacent source/drains 115, 120. Cross-section Y is parallel to the gate direction as indicated in FIG. 1.

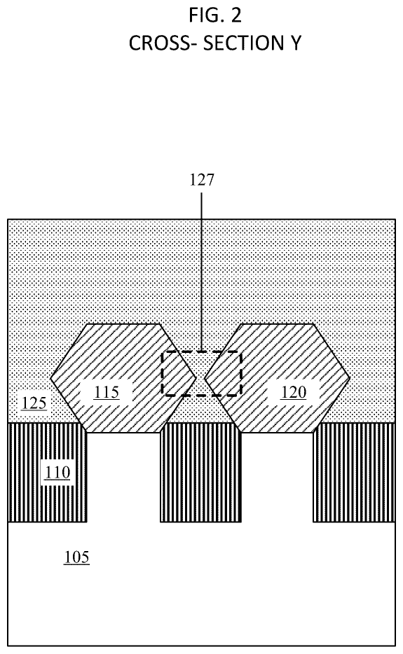

Referring now to FIG. 2 illustrates a structure during an intermediate step of a method of fabricating a nanosheet transistor according to an embodiment of the invention. FIG. 2 illustrates the processing stage after the formation of the source/drains. FIG. 2 illustrates a substrate 105, a shallow trench isolation layer 110, a first source/drain 115, a second source/drain 120, and an interlayer dielectric layer 125. The etching of the nanosheets (not shown) created a plurality of trenches (not shown) in the substrate 105. The trenches (nots shown) are filled in with a shallow trench isolation layer 110. The nanosheets (not shown) are recessed to form the source/drain region illustrated in the cross-section Y. The first source/drain 115 and the second source/drain 120 are formed on top of the substrate 105. An interlayer dielectric layer 125 is located around the first source/drain 115, and the second source/drain 120. Dashed box 127 emphasizes the region/area where the first source/drain 115 and the second source/drain 120 are close to each other. Having the source/drains this close to each other can lead to them shorting.

The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In some embodiments, substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 may be doped, undoped or contain doped regions and undoped regions therein.

The first source/drain 115, and the second source/drain 120, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

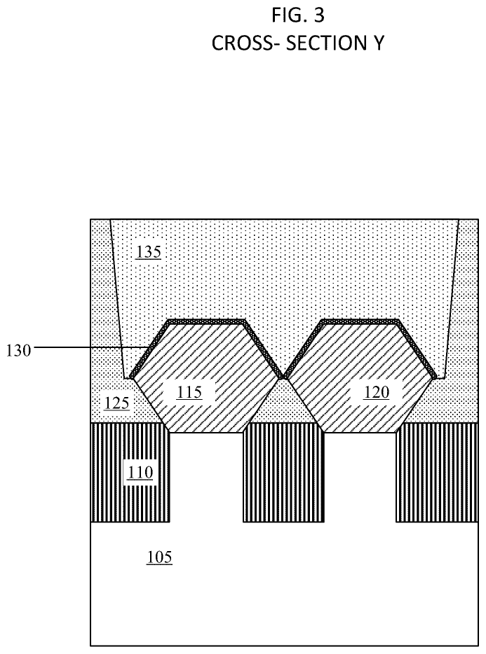

FIG. 3 illustrates the processing stage after the formation of a first semiconductor alloy liner 130 and a shared contact 135. A contact trench (not shown) was formed in the interlayer dielectric layer 125, where the contact trench (not shown) exposes a top surface of the first source/drain 115 and a top surface of the second source/drain 120. A first semiconductor alloy liner 130 is formed on the exposed top surfaces of the first source/drain 115 and the second source/drain 120. The first semiconductor alloy liner 130 can be comprised of, for example, a silicide like TiSi, NiSi, NiPtSi, nickel monosilicide, cobalt silicide (CoSi₂), a nickel silicide (NiSi₂), a palladium silicide (PdSi₂), a platinum silicide (PtSi₂), a tungsten silicide (WSi₂), molybdenum silicide (MoSi₂), zirconium silicide (ZrSi₂), ruthenium silicide (RuSi₂), or a similar material. A conductive metal is deposited to fill the rest of the contact trench to form the shared contact 135. The shared contact 135 is large enough to extend over the first source/drain 115 and the second source/drain 120.

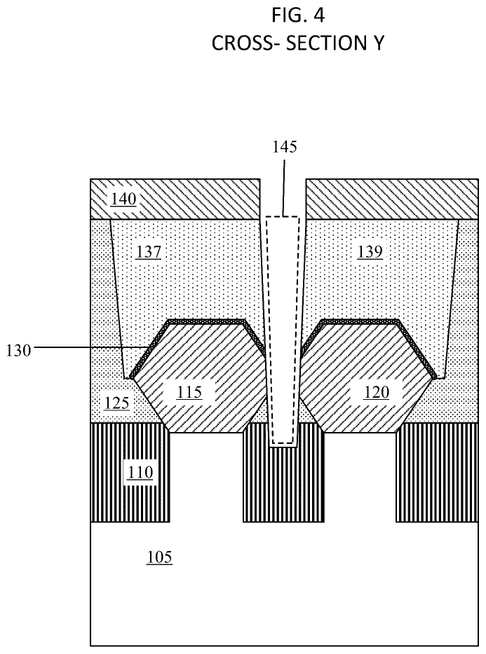

FIG. 4 illustrates the processing stage after the formation of a hardmask 140 and a shared contact cut 145. A hardmask 140 is formed on top of the interlayer dielectric layer 125 and the shared contact 135. The hardmask 140 is patterned and shared contact cut 145 is formed. The shared contact cut 145 is located between the first source/drain 115 and the second source/drain 120. The shared contact cut 145 divides the shared contact 135 into a first source/drain contact 137 and a second source/drain contact 139. The shared contact cut 145 further exposes a side surface of each the first source/drain 115 and the second source/drain 120. By having the shared contact cut 145 expose a side surface of each the first source/drain 115 and the second source/drain 120 allows for the lateral etching of the source/drains, which will be described in further detail below.

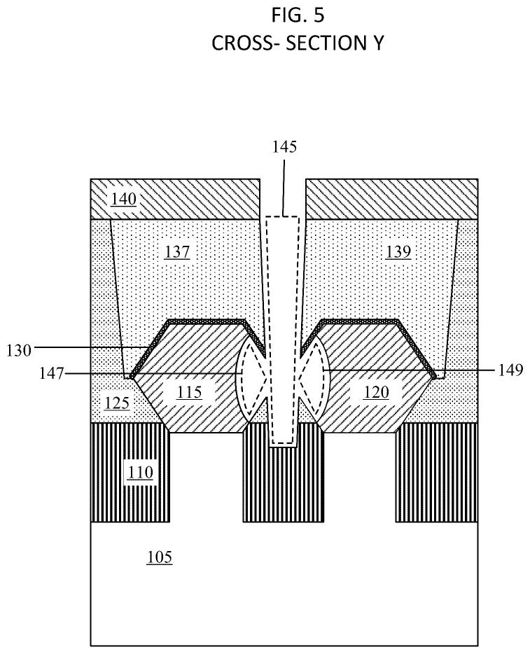

FIG. 5 illustrates the processing stage after a selective lateral etch of the source/drains. A selective etch process is used to etch the first source/drain 115 and the second source/drain 120. The first source/drain 115 and second source/drain 120 are accessible through the shared contact cut 145. The sidewalls of the first source/drain 115 and second source/drain 120 are exposed to the etching process, so the first source/drain 115 and second source/drain 120 are laterally etched. The lateral etching of the first source/drain 115 and second source/drain 120 causes the shape/profile of the source/drains 115, 120 to change. After the etching process, the first source/drain 115 and the second source/drain 120 have an asymmetrical shape/profile. A first cavity 147 is formed in the first source/drain 115 and a second cavity 149 is formed in the second source/drain 120. These cavities 147, 149 are connected to the shared contact cut 145. Portions of the first semiconductor alloy liner 130 is under cut by the lateral etching of the source/drains 115, 120, so that the first semiconductor alloy liner 130 forms the top wall/boundary of the cavities 147, 149. The first cavity 147 and the second cavity 149 increases the distance between the first source/drain 115 and the second source/drain 120, thus lowering the probability of the source/drains 115, 120 from shorting caused by their proximity.

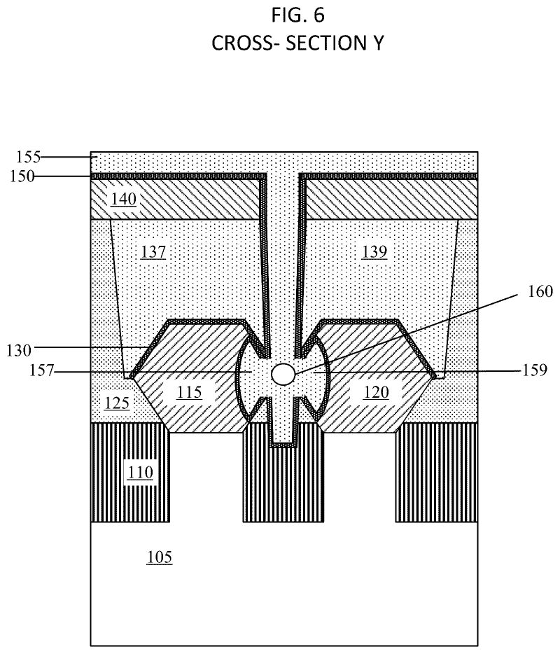

FIG. 6 illustrates the processing stage after the formation of a second semiconductor alloy liner 150 and formation of metal plugs 157, 159. A second semiconductor alloy liner 150 is formed on the exposed surface of the hardmask 140, along the sidewalls of the shared contact cut 145, and along the walls of the first cavity 147 and the second cavity 149. The second semiconductor alloy liner 150 is formed on the exposed surfaces (e.g., surfaces located within the first cavity 147 and the second cavity 149) of the first source/drain 115 and the second source/drain 120. The second semiconductor alloy liner 150 is formed on the bottom surface of the exposed portion of the first semiconductor alloy liner 130. The second semiconductor alloy liner 150 can be comprised of, for example, a silicide like TiSi, NiSi, NiPtSi, nickel monosilicide, cobalt silicide (CoSi₂), a nickel silicide (NiSi₂), a palladium silicide (PdSi₂), a platinum silicide (PtSi₂), a tungsten silicide (WSi₂), molybdenum silicide (MoSi₂), zirconium silicide (ZrSi₂), ruthenium silicide (RuSi₂), or a similar material. The second semiconductor alloy liner 150 and the first semiconductor alloy liner 130 can be the same material or a different material. The area where the first semiconductor alloy liner 130 and the second semiconductor alloy liner 150 overlap (e.g., at the top of the cavities 147, 149), will be the location where the semiconductor alloy material is the thickest (e.g., because of the combined thickness of the semiconductor alloy liners) when compared to other locations of the first semiconductor alloy liner 130 or the second semiconductor alloy liner 150. A metal fill layer 155 is formed on top of the second semiconductor alloy liner 150, such that the metal fill layer 155 fills the shared contact cut 145 and fills the first cavity 147 and the second cavity 149. It is possible that during the metal fill step that air gaps 160 can form in the metal fill layer 155. A first metal plug 157 extends into the first source/drain 115. Multiple surfaces of the first metal plug 157 are in contact with the second semiconductor alloy liner 150. A second metal plug 159 extends into the second source/drain 120. Multiple surfaces of the second metal plug 159 are in contact with the second semiconductor alloy liner 150. A first portion of the first semiconductor alloy liner 130 and the second semiconductor alloy liner 150 (e.g., the overlap area of the semiconductor alloy liners) extends over the top of the first metal plug 157. A second portion of the first semiconductor alloy liner 130 and the second semiconductor alloy liner 150 (e.g., the overlap area of the semiconductor alloy liners) extends over the top of the second metal plug 159.

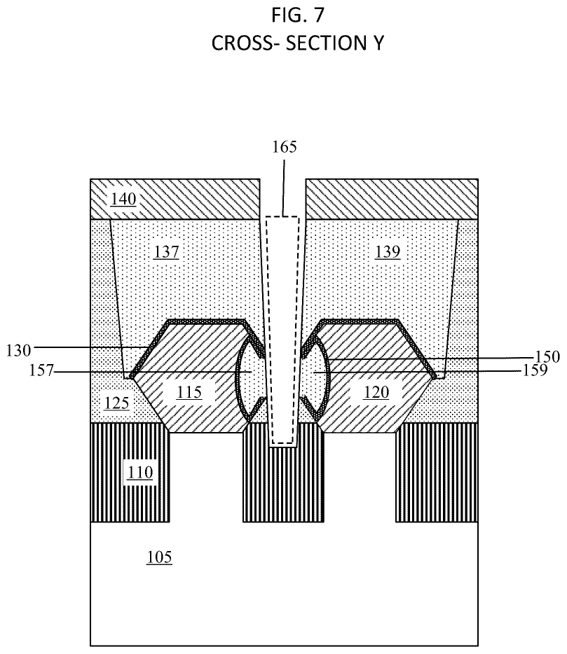

FIG. 7 illustrates the processing stage after the removal of excess materials and formation of cut trench 165. Excess second semiconductor alloy liner 150 and excess metal fill layer 155 material is removed and the contact trench 165 is formed in the metal fill layer 155. The contact trench 165 separates the first metal plug 157 and the second metal plug 159 from each other. Portions of the second semiconductor alloy liner 150 remains located between the metal plugs 157, 159 and the source/drains 115, 120, respectively. The first metal plug 157 and the second metal plug 159 have a sidewall exposed by the cut trench 165.

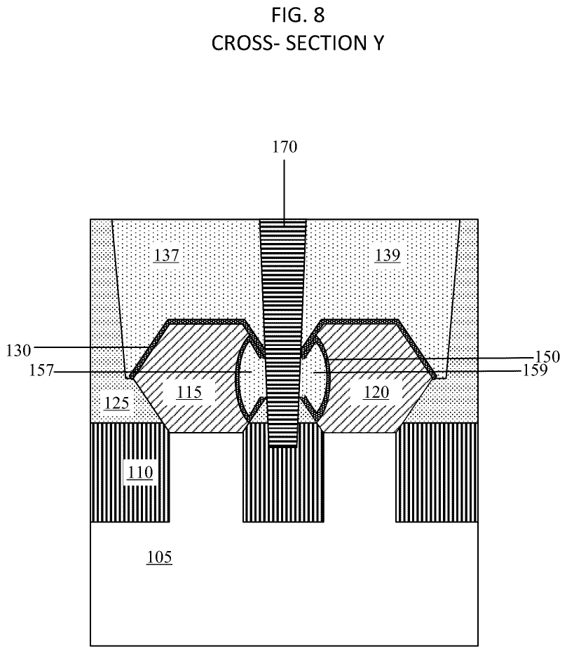

FIG. 8 illustrates the processing stage after the formation of a dielectric pillar 170. The contact trench 165 is filled with a dielectric material to form the dielectric pillar 170. Excess dielectric material and the hardmask 140 is removed, for example, by a chemical mechanical process (CMP). The dielectric pillar 170 is located between the first source/drain and the second source drain, between the first contact 137 and the second contact 139, and between the first metal plug 157 and the second metal plug 159. The dielectric pillar 170 is in contact with a sidewall of each the first metal plug 157 and the second metal plug 159, respectively. The dielectric pillar 170 separates and isolates a plurality of different components. The first semiconductor alloy liner 130 and the second semiconductor alloy liner 150 are in contact with the dielectric pillar 170.

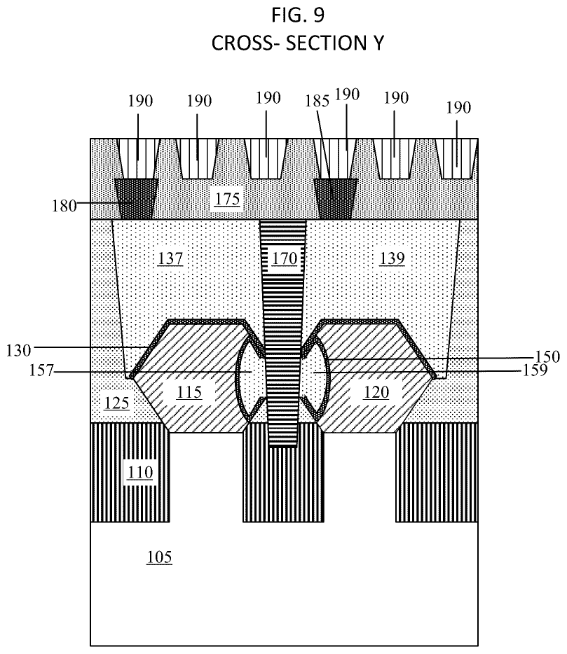

FIG. 9 illustrates the processing stage after the formation of additional interlayer dielectric material 175, contact vias 180, 185, and a plurality of metal lines 190. Additional interlayer dielectric material 175 is formed on top of the first contact 137, the second contact 139, and the interlayer dielectric layer 125. A plurality of trenches (not shown) are formed in the additional interlayer dielectric material 175. The trenches are filled with a conductive material to fill contact vias 180, 185, and a plurality of metal lines 190. The first source/drain 115 has an asymmetrical shape/profile caused by the removal of a portion of the first source/drain 115 to increase the distance between the adjacent source/drain. The first source/drain 115 is isolated from the second source/drain 120 by the dielectric pillar 170, the first metal plug 157, the second metal plug 159, and a plurality of sections of the second semiconductor alloy liner 150. The first source/drain 115 by itself has an asymmetrical shape, while the combination of the first source/drain 115, the second semiconductor alloy liner 150, and the first metal plug 157 has a symmetrical shape through cross-section Y. The second source/drain 120 by itself has an asymmetrical shape, while the combination of the second source/drain 120, the second semiconductor alloy liner 150, and the second metal plug 159 has a symmetrical shape through cross-section Y. Individually the first source/drain 115 and the second source/drain 120 have an asymmetrical shape, but have substantially symmetrical shape when viewed together.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first nanosheet transistor includes a first source/drain; and
a second nanosheet transistor includes a second source/drain;
wherein the first source/drain and the second source/drain are adjacent to each other, wherein each of the first source/drain and the second source/drain have an asymmetrical profile when cut through the first and second source/drain.

2. The microelectronic structure of claim 1, further comprising:
a first semiconductor alloy liner located on top of the first source/drain and on top of the second source/drain.

3. The microelectronic structure of claim 2, further comprising:
a second semiconductor alloy liner located adjacent a sidewall of the first source/drain and the second semiconductor alloy liner is located adjacent to a sidewall of the second source/drain.

4. The microelectronic structure of claim 3, further comprising:
a first overlap section located adjacent to the first source/drain;
a second overlap section located adjacent to the second source/drain;
wherein each the first and second overlap sections are formed by a portion of the first semiconductor alloy liner and the second semiconductor alloy liner overlapping each other.

5. The microelectronic structure of claim 4, wherein the first overlap section is thicker than the first semiconductor alloy liner and the first overlap section is thicker than the second semiconductor alloy liner, and wherein the second overlap section is thicker than the first semiconductor alloy liner and the second overlap section is thicker than the second semiconductor alloy liner.

6. The microelectronic structure of claim 5, further comprising:
a first metal plug located adjacent to the second semiconductor alloy liner, wherein a portion of second semiconductor alloy liner is located between the first metal plug and the first source/drain; and
a second metal plug located adjacent to the second semiconductor alloy liner, wherein a portion of second semiconductor alloy liner is located between the second metal plug and the second source/drain.

7. The microelectronic structure of claim 6, further comprising:
a dielectric pillar located between the first metal plug and the second metal plug.

8. The microelectronic structure of claim 7, wherein the first overlap section is located on top of the first metal plug and the second overlap section is located on top of the second metal plug.

9. A microelectronic structure comprising:
a first nanosheet transistor includes a first source/drain;
a second nanosheet transistor includes a second source/drain; and
a first source/drain contact and a second source/drain contact;
wherein the first source/drain and the second source/drain are adjacent to each other, wherein each of the first source/drain and the second source/drain have an asymmetrical profile when cut through the first and second source/drain, wherein the combined first source/drain and the second source/drain have a substantially symmetrical proofed when cut through the first and second source/drain.

10. The microelectronic structure of claim 9, further comprising:
a first semiconductor alloy liner located on top of the first source/drain and on top of the second source/drain.

11. The microelectronic structure of claim 10, wherein the first semiconductor alloy liner is located between the first source/drain contact and the first source/drain, wherein the first semiconductor alloy liner is located between the second source/drain contact and the second source/drain.

12. The microelectronic structure of claim 11, further comprising:
a second semiconductor alloy liner located adjacent a sidewall of the first source/drain and the second semiconductor alloy liner is located adjacent to a sidewall of the second source/drain.

13. The microelectronic structure of claim 12, further comprising:
a first overlap section located adjacent to the first source/drain;
a second overlap section located adjacent to the second source/drain;
wherein each the first and second overlaps sections are formed by a portion of the first semiconductor alloy liner and the second semiconductor alloy liner overlapping each other.

14. The microelectronic structure of claim 13, wherein the first overlap section is thicker than the first semiconductor alloy liner and the first overlap section is thicker than the second semiconductor alloy liner, and wherein the second overlap section is thicker than the first semiconductor alloy liner and the second overlap section is thicker than the second semiconductor alloy liner.

15. The microelectronic structure of claim 14, further comprising:
a first metal plug located adjacent to the second semiconductor alloy liner, wherein a portion of second semiconductor alloy liner is located between the first metal plug and the first source/drain; and
a second metal plug located adjacent to the second semiconductor alloy liner, wherein a portion of second semiconductor alloy liner is located between the second metal plug and the second source/drain.

16. The microelectronic structure of claim 15, further comprising:
a dielectric pillar located between the first metal plug and the second metal plug.

17. The microelectronic structure of claim 16, wherein the first overlap section is located on top of the first metal plug and the second overlap section is located on top of the second metal plug.

18. The microelectronic structure of claim 17, wherein the first overlap section is located between the first metal plug and the first source/drain contact, and wherein the second overlap section is located between the second source/drain and the second source/drain contact.

19. A method comprising:
forming a first nanosheet transistor includes a first source/drain;
forming a second nanosheet transistor includes a second source/drain;
forming a first semiconductor alloy liner on top of the first source/drain and the second source/drain;
forming a shared source/drain contact, wherein the shared source/drain contact extends over both the first source/drain and the second source/drain;
forming a first trench, wherein the first trench divides the shared source/drain contact in to a first source/drain contact and a second source/drain contact, wherein the first trench exposes the first source/drain and the second source/drain; and
laterally etching the first source/drain and the second source/drain, wherein the laterally etching extends outwards from the first trench, wherein after the lateral etching process each of the first source/drain and the second source/drain have an asymmetrical profile when cut through the first and second source/drain.

20. The method of claim 19, further comprising:
forming a second semiconductor alloy liner in a first cavity formed in the first source/drain from the lateral etching process;
forming the second semiconductor alloy liner in a second cavity formed in the second source/drain from the lateral etching process;
filling the first trench, the first cavity, and the second cavity with a metal fill;
forming a second trench to separate a first metal plug and a second metal plug, wherein the first metal plug is located adjacent to the first source/drain and the second metal plug is located adjacent to the second source/drain; and
forming a dielectric pillar by filling the second trench with a dielectric material.
